(19) United States
(12) Patent Application Publication
(10) Pub. No.: US 2006/0192262 A1
(43) Pub. Date: Aug. 31, 2006

(54) CMOS image sensor

(75) Inventor: Norio Kikuchi, Kitakami-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/360,691

(22) Filed: Feb. 24, 2006

(30) Foreign Application Priority Data
Feb. 25, 2005 (JP) 2005-051172

(51) Int. Cl. H01L 31/00

(52) U.S. Cl. 257/443

(57) ABSTRACT

Unit cells 2n1 and 2n2 arranged two-dimensionally in a row direction and a column direction includes a cell with four pixels as a set arranging pixels having an oblong shape and lengthwise shape alternatively with floating junctions FJ1 and FJ2 taken as centers; a plurality of reading transistors (Tr1 to Tr4) connected to the floating junction; reset transistors Tr15 and Tr25 arranged at one row end portion between the cells in the adjacent row directions, and address transistors Tr17 and Tr27 arranged at the other row end portion; amplifier transistors Tr16 and Tr26 connected in series to this address transistor, and moreover, arranges a reset wire ADD/RST-2 between the rows of the unit cell arranged in the row direction.

### CROSS-REFERENCE TO RELATED APPLICATION

This application is based upon and claims the benefit of priority from the prior Japanese Patent Application No. 2005-051172, filed of Feb. 25, 2005, the entire contents of which are incorporated herein by reference.

### BACKGROUND OF THE INVENTION

1. Field of the Invention

The present invention relates to a CMOS image sensor arranging a plurality of unit cells on a semiconductor substrate in a matrix pattern, and relates to an arrangement of pixels configuring the image sensor and reading of signals.

2. Description of the Related Art

As is well known, since a CMOS image sensor can be fabricated by a CMOS (Complementary Metal Oxide Semiconductor) technology widely used as a semiconductor device and has low electric power consumption, and the miniaturization thereof is possible, it is used as the solid-state image sensor of a digital camera, mobile equipment, or the like, and can be configured on one chip including a peripheral circuit such as a signal processing unit.

The CMOS image sensor arranges s a plurality of unit cells for photoelectric conversion on a semiconductor substrate in a matrix pattern, and one unit cell includes a pixel configured by a plurality of photo diodes, an amplifier transistor, an address transistor for selecting a row address, and a reset transistor. A plurality of these unit cells are arranged two-dimensionally in horizontal and vertical directions so as to form a pixel portion, and in the vicinity of the pixel portion, a horizontal line scanning circuit, a vertical line scanning circuit, a timing generating circuit, and the like are arranged, and a reading portion for reading the charge detected in each pixel is provided.

U.S. Pat. No. 6,657,665 discloses an image sensor arranging a plurality of pixels on a semiconductor substrate in row and column directions and including a pixel configured by photo diodes, a transistor selecting a row address and a reset transistor.

Further, a CMOS image sensor, which has in common a detecting circuit configured by an amplifier transistor, a reset transistor and an address transistor for a plurality of photo diodes (pixels) is known.

Japanese Patent Application Laid-Open No. 2004-153253 discloses an example of CMOS image sensors in which an amplifier transistor and other elements are shared by a pair of photo diodes (pixels). In this CMOS image sensor, if the number of pixels connected to one detecting circuit is increased, an area occupied by the detecting circuit per one pixel is then reduced so that the relative area of the pixel can be expanded, and improvement of characteristics of the CMOS image sensor can be expected.

However, the structure of the current CMOS sensor has the following problems. If the number of pixels connected to one detecting circuit is increased, parasitic capacitance of a floating junction which detects the electric charge detected by each pixel increases, and as a result, light conversion efficiency is reduced. Further, depending on an arrangement of the detecting circuit, there sometimes causes a shade portion where a light does not enter in the detecting circuit. In case for the detecting circuit adapted to a digital camera, there shows a line on the screen of the camera due to the shade portion, thereby causing deterioration of the quality.

### BRIEF SUMMARY OF THE INVENTION

According to an aspect of the invention, there is provided a CMOS image sensor arranging a plurality of photoelectric conversion unit cells in a matrix pattern two-dimensionally in row and column directions, wherein each of the unit cells comprises: a cell comprising a plurality of pixels as a set; reading transistors for reading signals subjected to photoelectric conversion, each of which is correspondingly provided to each the pixels; a reset transistor; an address transistor; and an amplifier transistor amplifying and outputting signals from the plurality of reading transistors, and wherein an address/reset wire is provided between the rows of the unit cells arranged in the row direction, an address signal being supplied through the address/reset wire to the address transistor located on the adjacent upper row, and a reset pulses being supplied through the address/reset wire to the reset transistor located on the adjacent lower row, and a reading line is provided in the row direction of the unit cell, a reading pulse being supplied through the reading line to the reading transistor, and a signal line is provided in the column direction, the signal read by the reading transistor being outputted through the signal line.

According to another aspect of the present invention, there is provided a CMOS image sensor arranging a plurality of photoelectric conversion unit cells in a matrix pattern two-dimensionally in row and column directions, wherein the each unit cell comprises: a cell of four pixels as a set comprising first and second pixels having either one shape of an oblong shape or a lengthwise shape and third and fourth pixels having other shape, wherein the pixel having an oblong shape and a pixel having a lengthwise shape are alternatively arranged about a base point as s center on a semiconductor substrate; a plurality of reading transistors each of which is correspondingly provided to the pixel and connected to a floating junction arranged at the base point so as to read the signals subjected to the photoelectric conversion; a reset transistor arranged in one row end between the cells in the adjacent column direction when the cell is arranged in plurality in a matrix pattern, an address transistor regularly arranged in another row end between cells in the adjacent row direction; and an amplifier transistor provided in common for the cell having four pixels as a set and connected in series with the address transistor so as to amplify and output the signals from the plurality of reading transistors.

### BRIEF DESCRIPTION OF THE DRAWINGS

FIG. 1 is an entire block diagram explaining an embodiment of a CMOS image sensor of the present invention,

FIG. 2 is a circuit diagram explaining a unit cell in an embodiment of the CMOS image sensor of the present invention,

FIG. 3 is a timing chart explaining a reading operation of each unit cell in an embodiment of the CMOS image sensor of the present invention,

FIG. 4 is a plan view explaining a pixel arrangement in an embodiment of the CMOS image sensor of the present invention,

FIG. 5 is an enlarged plan view showing a unit cell of FIG. 4; and

FIG. 6 is a sectional view taken along the line 6-6′ in FIG. 4.

### DETAILED DESCRIPTION OF THE INVENTION

An embodiment of the present invention will be described below in detail with reference to the drawings. In the drawings, the same component parts will be attached with the same reference numerals.

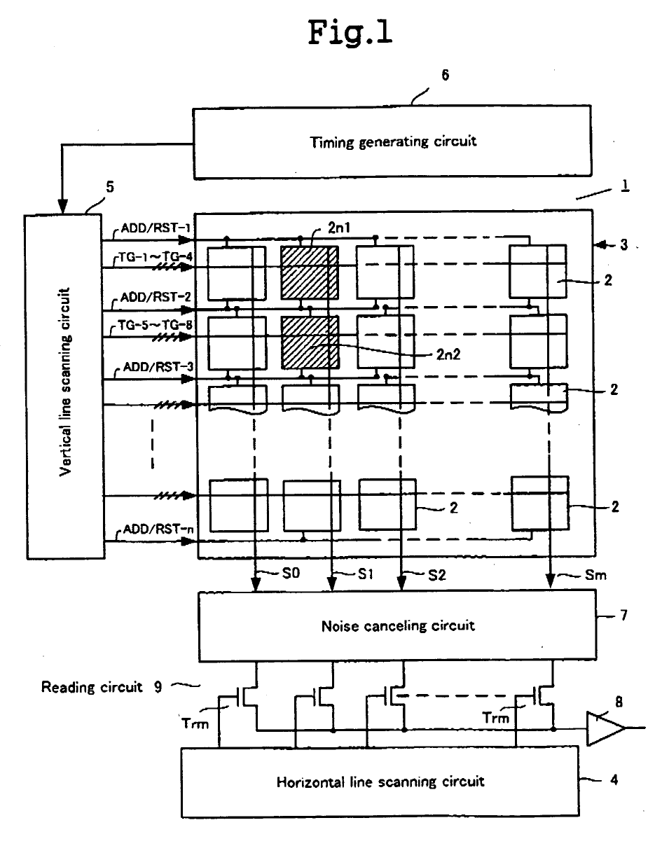

FIG. 1 is a block diagram showing an entire structure of an embodiment of a CMOS image sensor of the present invention.

In FIG. 1, a CMOS image sensor 1 includes a pixel portion having a two dimensional matrix pattern by arranging a plurality of unit cells 2 in m horizontal rows and n vertical columns. A horizontal line scanning circuit 4, a vertical line scanning circuit 5, a timing generating circuit 6, and a noise canceling circuit 7 are arranged in the peripheral portion of the pixel portion 3, and further the CMOS image sensor 1 includes a reading circuit 9 including an output amplifier 8.

The pixel portion 3 is provided with address/reset wires ADD/RST-1, ADD/RST-2, and ADD/RST-3 with two unit cells 2n1 and 2n2 adjacent in the row direction taken as a set, and reading lines (TG-1 to TG-4) and (TG-5 to TG-8) with respect to a plurality of pixels (four pixels in the present example) inside each unit cell 2. These address/reset wires (AD/SRT-1 to AD/SRT-3) and reading lines (TG-1 to TG-8) are connected in common to other unit cells 2 in the same row as the unit cells 2n1 and 2n2.

Further, the signal lines S0, S1, S2, . . . Sm are connected to a reading circuit 9 through a noise canceling circuit 7. The reading circuit 9 has a plurality of transistors Trm for column selection which are connected to each signal line S0 to Sm, and by allowing these transistors Trm to be selectively operated by the horizontal line scanning circuit 4, output signals can be obtained through the amplifier 8.

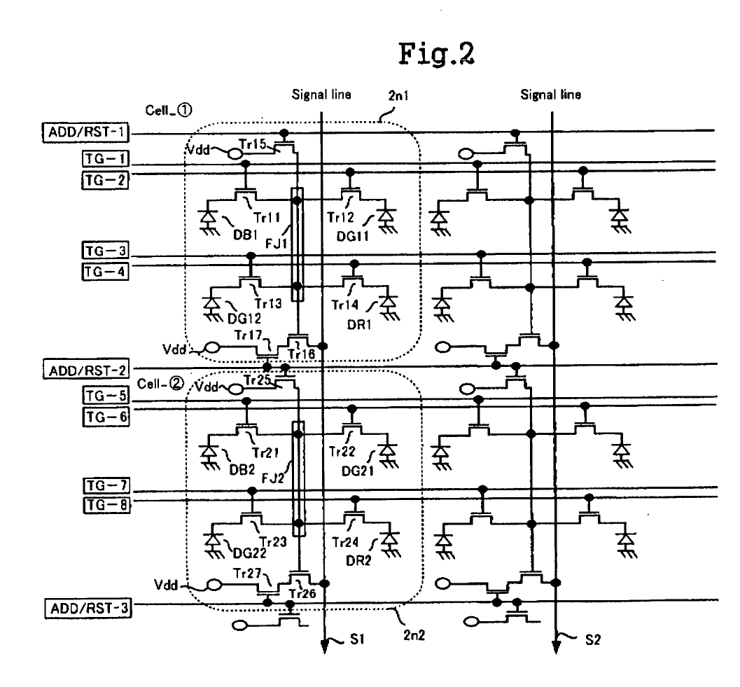

FIG. 2 shows an enlarged unit cell 2 of the pixel portion 3, and the structure thereof will be described with two unit cells 2n1 and 2n2 (shaded cells of FIG. 1) adjacent in the row direction taken as a representative. The unit cell 2n1 is provided with pixels including four photo diodes DG11, DG12, DB1, and DR1, and the photo diodes DG11 and DGl2 detect a green light, the photo diode DB1 detects a blue light, and the photo diode DR1 detects a red light, and the photo diodes can output electric charges subjected to photoelectric conversion.

Each of the photo diodes DB-1, DG-11, DG-12, and DR-1 are connected to the sources of reading transistors Tr11, Tr12, Tr13 and Tr14, and the drains of these transistors (Tr11 to Tr14) are connected to the source of a reset transistor Tr15 and the gate of the amplifier transistor Tr16. Further, the source of the amplifier transistor Tr16 is connected to the signal line S1, and the drain thereof is connected to the source of an address transistor Tr17, and the drains of the reset transistor Tr15 and the address transistor Tr17 are connected to a power terminal Vdd, and the drains of the reading transistors Tr11, Tr12, Tr13, and Tr14 are connected to a floating junction FJ1.

On the other hand, the unit cell 2n2 has also the same structure, and is configured by a pixel including photo diodes DB2, DG21, DG22, and DR2, reading transistors Tr21, Tr22, Tr23, and Tr24, a rest transistor Tr25, an amplifier transistor Tr26, an address transistor Tr27, and a power terminal Vdd and a floating junction FJ2.

Further, the gate of the reset transistor Tr15 of the unit cell 2n1 is connected to the address/reset wire ADD/RST-1, and the gates of the address transistor Tr17 of the unit cell 2n1 and a reset transistor Tr25 of the unit cell 2n2 are connected to the address/reset wire ADD/RST-2, and further, the gate of an address transistor Tr27 of the unit cell 2n2 is connected to the address/reset wire ADD/RST-3.

Further, the unit cells 2 arranged in the row direction of the unit cells 2n1 and 2n2, respectively is also similarly connected with the address/reset wires (ADD/RST-1 to ADD/RST-3). In FIG. 2, while a description has been made with the rows of the unit cells 2n1 and 2n2 as representatives, in reality, the same unit cells are arranged in the column direction, and the address/reset wires are wired, thereby configuring a pixel portion 3.

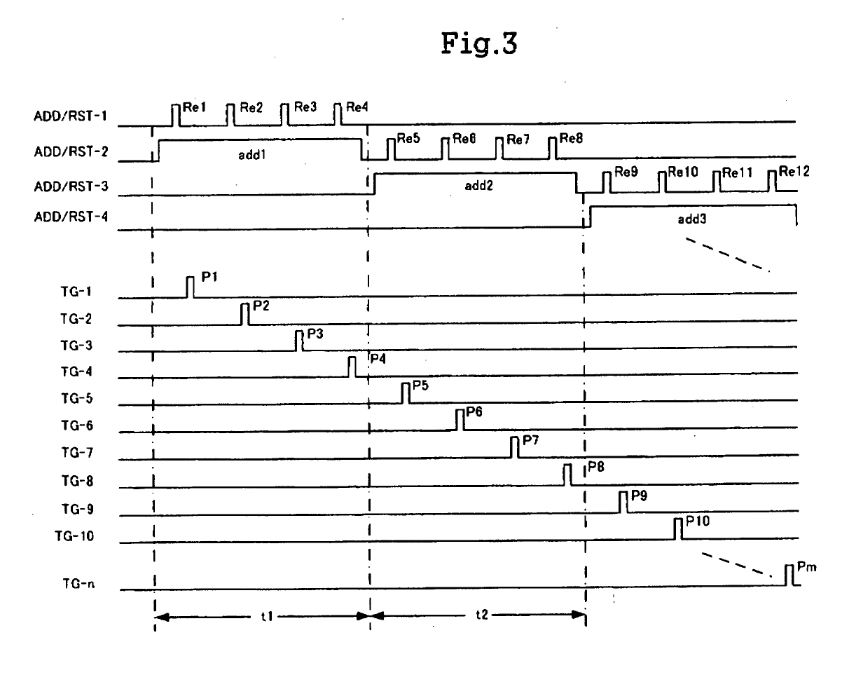

Next, the reading operation of such electric charge subjected to photoelectric conversion by the pixel portion 3 will be described by using a timing chart of FIG. 3. In FIG. 3, an axis of abscissas shows a time, and an axis of ordinate shows the signal waveforms of the address/reset wires (ADD/RST-1 to ADD/RST-3) and the signal waveforms of the reading lines (TG-1 to TG-4) and (TG-5 to TG-8), and a period t1 represents a timing for reading the unit cell 2n1, and a period t2 represents a timing for reading the unit cell 2n2.

That is, in the period t1, the address/reset wire ADD/RST-1 is periodically supplied with four reset pulses Re1, Re2, Re3, and Re4, and the address/reset wire ADD/RST-2 is supplied with an address signal add 1 of a high level (Hi), and the address/reset wire ADD/RST-3 is supplied with a signal of a low level (Low). In this manner, the address transistor Tr17 of the unit cell 2n1 can perform an on-operation by the address signal add 1 of the high level (Hi) supplied to that gate, and the unit cell 2n1 is put into an address selected state.

Further, a reading pulse P1 is output to the reading line TG-1 slightly behind the generation of the reset pulse Re1, and is supplied to the gate of the reading transistor Tr11. Consequently, after being reset by the reset pulse Re1, the transistor Tr11 is turned on, and the electric charge of the photo diode DB1 is read and amplified by the amplifier transistor Tr16, and a blue detected signal is outputted in the signal line S1.

Similarly, the reading pulse P2 is outputted slightly behind the generation of the reset pulse Re2 and is supplied to the gate of reading transistor Tr12, and after being reset by the reset pulse Re2, the transistor Tr12 is turned on, and the electric charge of the photo diode DG11 is read and amplified by the amplifier transistor Tr16, and a green detected signal is outputted in the signal line S1.

Further, the reading pulse P3 is outputted slightly behind the generation of the reset pulse Re3 and is supplied to the gate of the reading transistor Tr13, and after being reset by the reset pulse Re3, the transistor Tr13 is turned on, and the electric charge of the photo diode DG12 is read and amplified by the amplifier transistor Tr16, and a green detected signal is outputted in the signal line S1.

Further, the reading pulse P4 is outputted slightly behind the generation of the reset pulse Re4 and is supplied to the gate of the reading transistor Tr14, and after being reset by the reset pulse Re4, the transistor Tr14 is turned on, and the electric charge of the photo diode DR1 is read and amplified by the amplifier transistor Tr16, and a red detected signal is outputted in the signal line S1.

Note that, in the period t1, since the address/reset wire ADD/RST-3 is supplied with the signal of a low level (low), the address transistor Tr27 of the unit cell 2n2 is in an off state, and therefore, the amplifier transistor Tr26 connected in series with the transistor Tr27 is also put into an off state, and the unit cell 2n2 is not address-selected.

On the other hand, in the period t2, the address/reset wire ADD/RST-1 is supplied with the signal of a low level (low), the address/reset wire ADD/RST-2 is periodically supplied with four reset pulses Re5, Re6, Re7, and Re8, and the address/reset wire ADD/RST-3 is supplied with an address signal add2 of a high level (Hi). In this manner, the address transistor Tr27 of the unit cell 2n2 can perform an on-operation by the address signal add2 of a high level (Hi) supplied to that gate, and the unit cell 2n2 is put into an address selected state.

Further, a reading pulse P5 is output to the reading line TG-5 slightly behind the generation of the reset pulse Re5, and is supplied to the gate of the reading transistor Tr21 of the unit cell 2n2. Consequently, after being reset by the reset pulse Re5, the transistor Tr21 is turned on, and the electric charge of the photo diode DB2 is read and amplified by the amplifier transistor Tr26, and a blue detected signal is outputted in the signal line S1.

Similarly as described above, by the reset pulses Re6, Re7, and Re8, and the reading pulses P6, P7, and P8, the transistors Tr22 to Tr24 are turned on in order, and the electric charges of the photo diodes DG21, DG22, and DR2 are read. As a result, the signal line S1 is outputted with a green detected signal and a red detected signal amplified by the amplifier transistor Tr26.

Further, subsequent to the period t2, similarly, the reset pulses (Re9 to Re12) are supplied from the address/reset wire ADD/RST-3, and the address signal add3 is supplied from the address/reset wire ADD/RST-4, and the reading of the unit cells of the next row is performed. The address signals, the reset signals, and the pulses (P1 to P8) which are supplied to the reading lines (TG1 to TG8) are controlled in supply timing by the timing generating circuit 6 and are generated from the vertical line scanning circuit 5.

Further, the reading operation is performed with the similar timing for the other unit cell 2 arranged in the same row as the unit cells 2n1 and 2n2, but which signal line of the column is selected can be decided by turning on and off the transistors Trm of the reading portion 9 under the control of the horizontal line scanning circuit 4.

Note that, in FIG. 1, only the reset pulse is supplied from the address/rest wire ADD/RST-1 located at the upper most row, and only the address signal is supplied for the address/reset wire ADD/RST-n located at the lowermost row, and the address signal and reset pulse are supplied from the address/rest wire which is wired halfway between these wires.

Thus, according to the CMOS image sensor of the present invention, since the same wire can be used for the address/reset, the area occupied for the wire can be reduced, and the pixel area can be magnified.

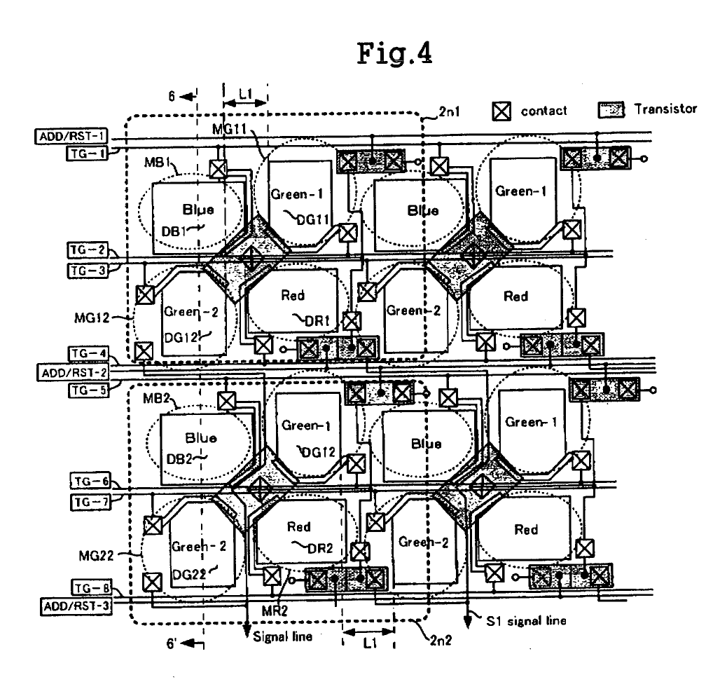

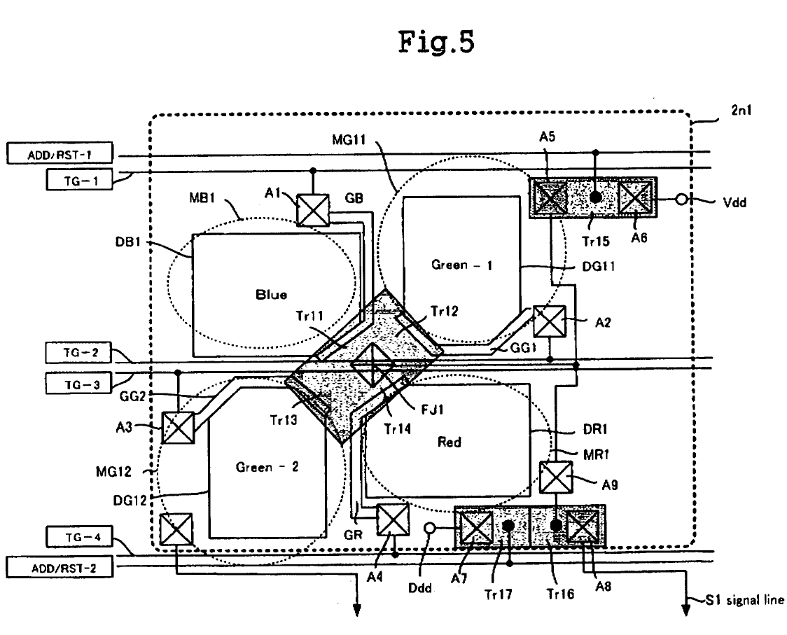

Next, a pixel arrangement structure of the CMOS image sensor of the present invention will be described with reference to FIGS. 4 and 5.

FIG. 4 is a plan view explaining the pixel arrangement in an embodiment of the CMOS image sensor of the present invention, and FIG. 5 is an enlarged plan view of one unit cell of FIG. 4. In FIG. 4, each unit cell is configured by four pixels of a pixel Blue for blue, pixels Green-1 and green-2 for green, and a pixel Red for red as one set.

Describing the unit cells 2n1 and 2n2 as representatives, the unit cell 2n1 has the photo diode DB1 forming a pixel for blue, two photo diodes DG11 and DG12 forming pixels for green, and the photo diode DR-1 forming a pixel for red, and the photo diode DB1 and the photo diode DR1 are arranged sidewise, and the photo diodes DG11 and DG12 are arranged lengthwise.

That is, the unit cell 2n1 takes, for example, the oblong shaped first and second pixels with a row direction taken as a long side as the pixels for Blue and Red from the oblong shapes and the lengthwise shapes, and the lengthwise shaped third and fourth pixels with a column direction taken as a long side as the pixels for Green-1 and Green-2, and the oblong shaped pixel and the lengthwise shaped pixel are alternatively arranged on a semiconductor substrate with a certain base point as a center, thereby configuring a cell with four pixels as a set.

In the center portion of each of these photo diodes, as shown in FIG. 5, the reading transistors (Tr11 to Tr14) are arranged, and the drains thereof are connected to the floating junction FJ1. That is, the floating junction FJ1 is provided at the base point portion.

The transistor Tr11 has its source connected to the photo diode DB1, and its gate GB connected to a contact A1, and the transistor Tr12 has its source connected to the photo diode DG11, and its gate GG1 connected to a contact A2. Similarly, the transistor Tr13 has its source connected to the photo diode DG12, and its gate GG2 connected a contact A3, and the transistor Tr14 has its source connected to the photo diode DR1 and its gate GR connected to a contact A4.

Further, the contacts A1, A2, A3, and A4 are connected to the reading lines TG1, TG2, TG3 and TG4, respectively, and the reading pulses P1, P2, P3, and P4 (see FIG. 3) are supplied to the gates GB, GG11, GG12, and GR of the transistors (Tr11 to Tr14), respectively.

Further, as shown in FIGS. 4 and 5, at the upper left of the blue pixel (at the right side of Green-1) is arranged the reset transistor Tr15, and its drain is connected to a voltage source Vdd through the contact A6, and its source is connected to the contact A5, and its gate is connected to the address/reset wire ADD/RST-1. Consequently, the reset transistor Tr15 is reset by the rest pulses (Re1 to Re4) from the address/reset wire ADD/RST-1.

Further, at the lower right of the pixel Red (the left side of Green-2) are arranged the address transistor Tr17 and the amplifier transistor Tr16. The drain of the address transistor Tr17 is connected the voltage source Vdd through the contact A7, and its gate is connected to the address/reset wire ADD/RST-2.

On the other hand, the source of the amplifier transistor Tr16 is connected to the contact A8, and its gate is connected to the contact A5 through the contact A9. The source of the transistor Tr17 and the drain of the transistor Tr16 are connected in common, and the contacts A5 and A9 are connected to the floating junction FJ1, and the contact A8 is connected to the signal line S1. Consequently, the address transistor Tr17 responses to an address signal add1 from the address/reset wire ADD/RST-2 (see FIG. 3), and the amplifier transistor Tr16 has its gate supplied with the signals from the transistors (Tr11 to Tr14), and can amplify and output these signals to the signal line S1.

That is, when the cells are arranged in a matrix pattern, the reset transistor Tr15 is regularly arranged at one row end portion (upper side) between adjacent cells in the row direction, and the address transistor Tr17 is regularly arranged at the other row end portion (lower side) between adjacent cells in the row direction, and the amplifier transistor Tr16 is provided in common for the cell of four pixels as a set, and is connected in series to the address transistor Tr17 and amplifies and outputs the signals from a plurality of reading transistors (Tr11 to Tr14).

Similarly, the unit cell 2n2, as shown in FIG. 4, has the photo diode DB2 to form the pixel for Blue, two photo diodes DG21 and DG22 for to form the pixels for Green, and the photo diode DR2 to form the pixel for Red, and the photo diode DB2 and the photo diode DR2 are arranged sideways, and the photo diodes DG21 and DG22 are arranged lengthwise. Note that the cell unit 2n2 is the same as the unit cell 2n1 of FIG. 5 in structure and arrangement except that the unit cell 2n1 responses to the reset signals (Re5 to Re8) from the address/reset wire ADD/RST-2 and the address signal add2 from the address/reset wire ADD/RST-3 and the reading signals (TG5 to TG8) shown in FIG. 3.

Consequently, when taking into consideration the rows of the unit cell 2n1 and 2n2, the address/reset wire ADD/RST-2 supplies the address signal to the address transistor located at the adjacent upper row and supplies the reset pulse to the reset transistor located at the adjacent lower row.

Further, as shown in FIG. 4, while the pixels for Blue and Red are shaped oblong, the pixels for Green-1 and Green-2 are shaped lengthwise, and thus, the shapes are different. Hence, as evident from FIG. 4, a space portion is formed at the lower right of the pixel for Red and at the upper left of the pixel for Blue, and therefore, the reset transistor Tr15, the address and amplifier transistors Tr16 and Tr17 can be arranged in this space. Note that the Blue and Red pixels and the Green-1 and Green-2 pixels are allowed to be identical in area, while being different in shape. In this manner, a pixel interval L1 can be set almost equal by extending the Blue and Red pixels crosswise and the Green-1 and Green-2 pixels lengthwise, and light receiving portions can be uniformly arranged.

Further, as shown in FIG. 5, the reading transistors (Tr11 to Tr14) are arranged at the center of four pixels so that the floating junction FJ1 can be efficiently shared in common by the four pixels, thereby controlling the increase of a parasitic capacitance and preventing a signal amplification factor from deteriorating.

Further, as shown in FIGS. 4 and 5, micro lenses MB1, MG11, MG12, MR1 . . . are arranged in opposition to each of the pixels Blue, Green-1, Green-2, and Red. For example, the micro lens MB1 for Blue and the micro lens MR1 for Red are shape oblong, and the micro lenses MG11 and MG12 for Green-1 and Green-2 are approximately shaped circular so that a light can be converged into the center portions of the pixels, even if different in the shapes.

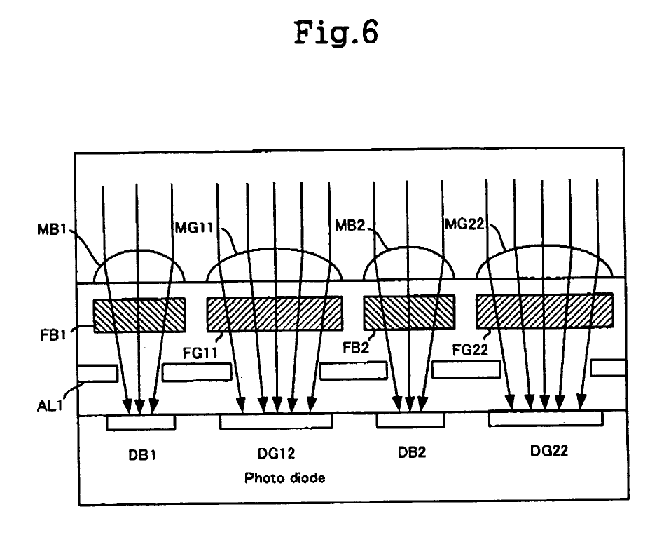

FIG. 6 is a sectional view taken along the line 6-6′ in FIG. 4 and schematically shows a relationship between the micro lenses and the photo diodes.

In FIG. 6, the photo diodes DB1, DG12, DB2, and DG22 are provided on the semiconductor substrate, and the micro lenses MB1, MG11, MB2, and MG22 are arranged in opposition to these photo diodes, and between the photo diodes and the micro lenses, blue color filters FB1 and FB2, and green color filters FG11 and FG12 are arranged. Further, between the color filters and the photo diodes, a shielding layer AL1 which prevents a color mixture between the adjacent pixels is arranged.

According to the CMOS image sensor of the present invention, since the address/reset wire ADD/RST-2 can be shared for use of the address and rest, the wiring is simplified. Therefore, a ratio of pixel area can be enlarged by that much, and photoelectric conversion factor can be enhanced.

Note that the embodiment of the present invention is not limited to the above-described description, and various modifications may be made to the embodiment. For example, though a description has been made on the reading sequence of the detected signals which are read from the pixels Blue, Green-1, green-2, and Red in order from one unit cell, the reading may be performed by another sequence making a round of the pixels. Further, though the pixels of Blue and Red have been shaped oblong and the pixels of Green-1 and Green-2 shaped lengthwise, reversely the pixels of Blue and Red may be shaped lengthwise, and the pixels of Green-1 and Green-2 may be shaped oblong. Further, with respect to the shape of the micro lenses, the micro lenses of Green-1 and green-2 may be shaped according to the actual situation such as an oval shape and the like.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the present invention.

What is claimed is:

1. A CMOS image sensor arranging a plurality of photoelectric conversion unit cells in a matrix pattern two-dimensionally in row and column directions,
wherein each of the unit cells comprises: a cell comprising a plurality of pixels as a set; reading transistors for reading signals subjected to photoelectric conversion, each of which is correspondingly provided to each the pixels; a reset transistor; an address transistor; and an amplifier transistor amplifying and outputting signals from the plurality of reading transistors, and
wherein an address/reset wire is provided between the rows of the unit cells arranged in the row direction, an address signal being supplied through the address/reset wire to the address transistor located on the adjacent upper row, and a reset pulse being supplied through the address/reset wire to the reset transistor located on the adjacent lower row, and a reading line is provided in the row direction of the unit cell, a reading pulse being supplied through the reading line to the reading transistor, and a signal line is provided in the column direction, the signal read by the reading transistor being outputted through the signal line.

2. The CMOS image sensor according to claim 1, wherein the address signals are supplied to the address transistor located on the upper row from the address/reset wire, and subsequently, the reset pulses are supplied to the reset transistor located on the lower row, and the reading transistors are sequentially supplied with reading pulses in the address signal period for the unit cell being supplied with the address signals.

3. The CMOS image sensor according to claim 2, wherein the reset pulses are supplied to the reset transistor in the address signal period prior to supplying the reading pulses to the reading transistor.

4. The CMOS image sensor according to claim 1, wherein each of the unit cells comprises:
an address transistor having a drain electrode connected to a voltage source and a gate electrode supplied with the address signals;
an amplifier transistor having drain and source electrodes connected between the source electrode of the address transistor and the signal line;
a reset transistor having a drain electrode connected to the voltage source and a gate electrode supplied with the reset pulses, and a source electrode connected to the gate electrode of the amplifier transistor;
a plurality of photo diodes configuring the plurality of pixels; and
a reading transistors having source electrodes connected to the photo diodes and drain electrodes connected to the gate electrode of the amplifier transistor, and gate electrodes supplied with the reading pulses.

5. A CMOS image sensor arranging a plurality of photoelectric conversion unit cells in a matrix pattern two-dimensionally in row and column directions,
Wherein the each unit cell comprises:
a cell of four pixels as a set comprising first and second pixels having either one shape of an oblong shape or a lengthwise shape and third and fourth pixels having other shape, wherein the pixel having an oblong shape and a pixel having a lengthwise shape are alternatively arranged about a base point as s center on a semiconductor substrate;
a plurality of reading transistors, each of which is correspondingly provided the pixel and connected to a floating junction arranged at the base point so as to read the signals subjected to the photoelectric conversion;
a reset transistor arranged in one row end between the cells in the adjacent column direction when the cell is arranged in plurality in a matrix pattern,
an address transistor arranged in another row end between cells in the adjacent row direction; and
an amplifier transistor provided in common for the cell having four pixels as a set and connected in series with the address transistor so as to amplify and output the signals from the plurality of reading transistors.

6. The CMOS image sensor according to claim 5, wherein the areas of the first and second pixels and the third and fourth pixels are made approximately equal.

7. The CMOS image sensor according to claim 5, wherein the first and second pixels have an oblong shape with a row direction taken as a long side, and the third and fourth pixels have a lengthwise shape with a column direction taken as a long side.

8. The CMOS image sensor according to claim 5, wherein the reset transistor is arranged in a space portion formed at one end portion in the row direction, and the address transistor and amplifier transistor are arranged in a space portion formed at another end portion in the row direction when the four pixels are alternatively arranged with the base point taken as a center.

9. The CMOS image sensor according to claim 5, wherein the plurality of reading transistors have each drain electrode connected to the floating junction, and each gate electrode provided in the peripheral portion of the floating junction, and each gate electrode supplied with the reading pulses.

10. The CMOS image sensor according to claim 5, wherein the first and second pixels are pixels for Blue and Red, respectively, and the third and fourth pixels are pixels for Green.

11. The CMOS image sensor according to claim 5, wherein micro condensing lens are arranged in opposition to the first and second pixels and the third and fourth pixels.

12. The CMOS image sensor according to claim 11, wherein the micro condensing lens have a shape corresponding to the first and second pixels and the third and fourth pixels.

13. The CMOS image sensor according to claim 11, wherein the micro lenses opposing to the first and second pixels are shaped approximately oval, and the micro lenses opposing to the third and fourth pixels are approximately shaped circular.

14. The CMOS image sensor according to claim 5, wherein an address/rest wire is provided between the rows of the unit cells arranged in the row direction, an address signal being supplied through the address/rest wire to the address transistor located on the adjacent upper row, and a reset pulses being supplied through the address/rest wire to the rest transistor located on the adjacent lower row, and a reading line is provided in the row direction of the unit cell, a reading pulse being supplied through the reading line to the reading transistors, and a signal line is provided in the column direction, the signal read by the reading transistor being outputted through the signal line.

15. A CMOS image sensor arranging a plurality of photoelectric conversion unit cells in a matrix pattern two-dimensionally in row and column directions,
wherein the each unit cell comprises:
a cell of four pixels as a set comprising first and second pixels having either one shape of an oblong shape or a lengthwise shape and third and fourth pixels having other shape, wherein the pixel having the oblong shape and the pixel having the lengthwise shape are mutually arranged at a base point as a center on a semiconductor substrate;
a plurality of reading transistors, each of which is correspondingly provided to the pixel and connected to a floating junction arranged at the base point so as to read the signals subjected to the photoelectric conversion;
a reset transistor arranged in one row end between the cells in the adjacent row direction when the cell is arranged in plurality in a matrix pattern,
an address transistor arranged in another row end between cells in the adjacent row direction; and
an amplifier transistor provided in common for a cell having four pixels as a set and connected in series with the address transistor so as to amplify and output the signals from the plurality of reading transistors, and
wherein an address/reset wire is provided between the rows of the unit cells arranged in the row direction, and an address signal being supplied through the address/reset wire to the address transistor located on the adjacent upper row, and a reset pulse being supplied through the address/reset wire to the reset transistor located on the adjacent lower row, and a reading line is provided in the row direction of the unit cell, a reading pulse being supplied through the reading line to the reading transistors, and a signal line is provided in the column direction, the signal read by the reading transistors being outputted through the signal line.

16. The CMOS image sensor according to claim 15, wherein each of the unit cells comprises;
an address transistor having a drain electrode connected to a voltage source and a gate electrode supplied with the address signals;
an amplifier transistor having drain and source electrodes connected between the source electrode of the address transistor and the signal line;
a reset transistor having a drain electrode connected to the voltage source and a gate electrode supplied with the reset pulses, and a source electrode connected to the gate electrode of the amplifier transistor;
a plurality of photo diodes configuring the plurality of pixels; and
a plurality of reading transistors having source electrodes connected to the photo diodes and drain electrodes connected to the gate electrode of the amplifier transistor, and gate electrodes supplied with the reading pulses.

17. The CMOS image sensor according to claim 15, wherein the first and second pixels are pixels for Blue and Red, and the third and fourth pixels are pixels for Green.

18. The CMOS image sensor according to claim 15, wherein the areas of the first and second pixels and the third and fourth pixels are made approximately equal.

19. The CMOS image sensor according to claim 15, wherein the first and second pixels have oblong shapes with a row direction taken as a long side, and the third and fourth pixels have lengthwise shapes with a column direction taken as a long side.

20. The CMOS image sensor according to claim 15, wherein the reset transistor is arranged in a space portion formed at one end portion in the row direction, and the address transistor and amplifier transistor are arranged in a space portion formed at another end portion in the row direction when the four pixels are alternatively arranged with the base point taken as a center.
